(19) United States
(12) Patent Application Publication
(10) Pub. No.: US 2009/0289625 A1
(43) Pub. Date: Nov. 26, 2009

(54) Sensor system

(75) Inventors: Jialou Hu, West Bloomfield, MI (US); Scott Kerby, Wolverine Lake, MI (US)

Correspondence Address: FOLEY AND LARDNER LLP;SUITE 500, 3000 K STREET NW, WASHINGTON, DC, 20007, US

(73) Assignee: TK Holdings Inc.

(21) Appl. No.: 12/458,930

(22) Filed: Jul. 28, 2009

Related U.S. Application Data
(63) Continuation-in-part of application No. 12/213,299, filed on Jun. 17, 2008.
(60) Provisional application No. 61/129,917, filed on Jul. 29, 2008.
(60) Provisional application No. 60/929,190, filed on Jun. 18, 2007.
(60) Provisional application No. 60/929,689, filed on Jul. 9, 2007.

(51) Int. Cl. G01N 27/72; G01R 33/12

(52) U.S. Cl. 324/234

(57) ABSTRACT

A sensor system includes an electrically conductive surface and an air coil in proximity to the electrically conductive surface. The air coil includes a first coil and a second coil. The first coil forms a wire winding pattern having a cross section perpendicular with the cross section of a wire winding pattern of the second coil. The sensor system also includes a controller electrically coupled to the air coil and configured to sense a change in impedance of the air coil due to relative movement between the air coil and the electrically conductive surface. The sensor system also includes a safety device electrically coupled to the controller.

### CROSS-REFERENCE TO RELATED PATENT APPLICATIONS

This application is a Continuation-In-Part of U.S. patent application Ser. No. 12/213,299, filed Jun. 17, 2008, which claims priority to U.S. Provisional Patent Application No. 60/929,190, filed Jun. 18, 2007 and U.S. Provisional Patent Application No. 60/929,689, filed Jul. 9, 2007. This application claims priority to and the benefit of U.S. Provisional Patent Application No. 61/129,917, filed Jul. 29, 2008. All of the foregoing applications are incorporated herein by reference in their entireties.

### BACKGROUND

The present disclosure relates generally to the field of air coil sensor systems. The disclosure more specifically relates to an air coil sensor system for actuating a safety device.

Conventional air coil sensor systems include a square or rectangular-shaped cross-sectional winding pattern that may be used to generate an electromagnetic effect with an electrically conductive (e.g., metal) surface. Movement of the metal surface towards the coil or away from the coil causes a change in the electromagnetic effect resulting in a change in impedance and inductance of the surface and coil. A controller may be used to sense this change in impedance or inductance. In a vehicle, this sensed change (e.g., resulting from an accident causing the vehicle body to buckle, dent, or move) may prompt the actuation of a safety device such as an airbag. Generally, adding winding turns to these rectangular or square shaped coil winding systems is a way to increase the intensity or sensitivity of the measurements. However, the total impedance level also increases with number of turns, and could be too high to be controlled. Thus the required driving power is high, resulting in additional cost.

### SUMMARY

According to one exemplary embodiment, a sensor system includes an electrically conductive surface and an air coil in proximity to the electrically conductive surface. The air coil includes a first coil and a second coil. The first coil forms a wire winding pattern having a cross section perpendicular with the cross section of a wire winding pattern of the second coil. The sensor system also includes a controller electrically coupled to the air coil and configured to sense a change in impedance of the air coil due to relative movement between the air coil and the electrically conductive surface. The sensor system also includes a safety device electrically coupled to the controller. The first and second coils may be integrally formed from a single wire. Thus, the first and second coils may be positioned in series.

According to another exemplary embodiment, an air coil includes a first coil and a second coil. The first coil forms a wire winding pattern having a cross section perpendicular with the cross section of a wire winding pattern of the second coil. The air coil is in proximity to an electrically conductive surface and is electrically coupled to a controller configured to sense a change in impedance of the air coil due to relative movement between the coil and the electrically conductive surface. The controller is electrically coupled to a safety device.

According to yet another exemplary embodiment, a sensor system includes an electrically conductive surface and an air coil in proximity to the electrically conductive surface. The air coil includes a first coil and a second coil. The first coil forms a wire winding pattern having a cross section perpendicular with the cross section of a wire winding pattern of the second coil. The sensor system also includes a controller electrically coupled to the air coil and configured to sense a change in impedance of the air coil due to relative movement between the air coil and the electrically conductive surface.

It is to be understood that both the foregoing general description and the following detailed description are exemplary and explanatory only, and are not restrictive of the invention as claimed.

### BRIEF DESCRIPTION OF THE DRAWINGS

These and other features, aspects, and advantages of the present invention will become apparent from the following description, appended claims, and the accompanying exemplary embodiments shown in the drawings, which are briefly described below.

FIG. 1 is a block diagram illustrating a sensor system that includes a coil according to an exemplary embodiment.

FIG. 2 is a schematic diagram illustrating the magnetic interaction of the coil of FIG. 1 with an electrically conductive surface according to an exemplary embodiment.

FIG. 3 is a circuit diagram illustrating the electrical coupling between the coil and electrically conductive surface of FIG. 1 according to one exemplary embodiment.

FIG. 4 is a schematic diagram illustrating section views of coil configurations in the sensor system of FIG. 1 according to various exemplary embodiments.

FIG. 5 is a graph illustrating the change in impedance between the coil and electrically conductive surface of FIG. 1 for coil shapes according to various exemplary embodiments.

FIG. 6 is a schematic diagram illustrating section views and information of coil configurations in the sensor system of FIG. 1 according to various exemplary embodiments.

FIG. 7 includes a number of graphs illustrating the magnitude signal modulation of the coil and electrically conductive surface of FIG. 1 with the coil configurations of FIG. 6, according to various exemplary embodiments.

FIG. 8 is a perspective view of the coil of FIG. 1 with an “L” shaped winding according to an exemplary embodiment.

FIG. 9 is a partial side view of a vehicle showing the door panel and adjoining beams.

FIG. 10A is an exploded isometric view of a two-piece “L” shaped winding according to one exemplary embodiment.

FIG. 10B is an isometric view of the two-piece “L” shaped winding of FIG. 10A.

FIG. 10C is a cross section of the two-piece “L” shaped winding of FIG. 10B taken along line 10C-10C.

FIG. 11A is an exploded isometric view of a two-piece “L” shaped winding according to another exemplary embodiment.

FIG. 11B is an isometric view of the two-piece “L” shaped winding of FIG. 11A.

FIG. 11C is a cross section of the two-piece “L” shaped winding of FIG. 11B taken along line 11C-11C.

FIG. 12A is a cross-section of an “L” shaped winding according to one exemplary embodiment.

FIG. 12B is a cross-section of an “L” shaped winding according to another exemplary embodiment.

FIG. 13 is a table showing the layout parameters of air coils according to several exemplary embodiments.

FIG. 14 is a table showing the impedance change between the coil and the electrically conductive surface when the coil has various exemplary coil winding patterns described in FIG. 13.

FIG. 15 is a graph showing the impedance change between the coil and the electrically conductive surface when the coil has various exemplary coil winding patterns described in FIG. 13.

### DETAILED DESCRIPTION

According to some exemplary embodiments, a sensor system may be similar to the various magnetic sensing systems described in U.S. Patent Publication Nos. 2008/0068008, 2007/0024277, World Intellectual Property Office Publication WO2007114870, and U.S. Pat. Nos. 7,212,895, 7,209,844, and 6,587,048, which are incorporated by reference herein in their entirety. The invention described below may be employed in combination with the sensor systems described above.

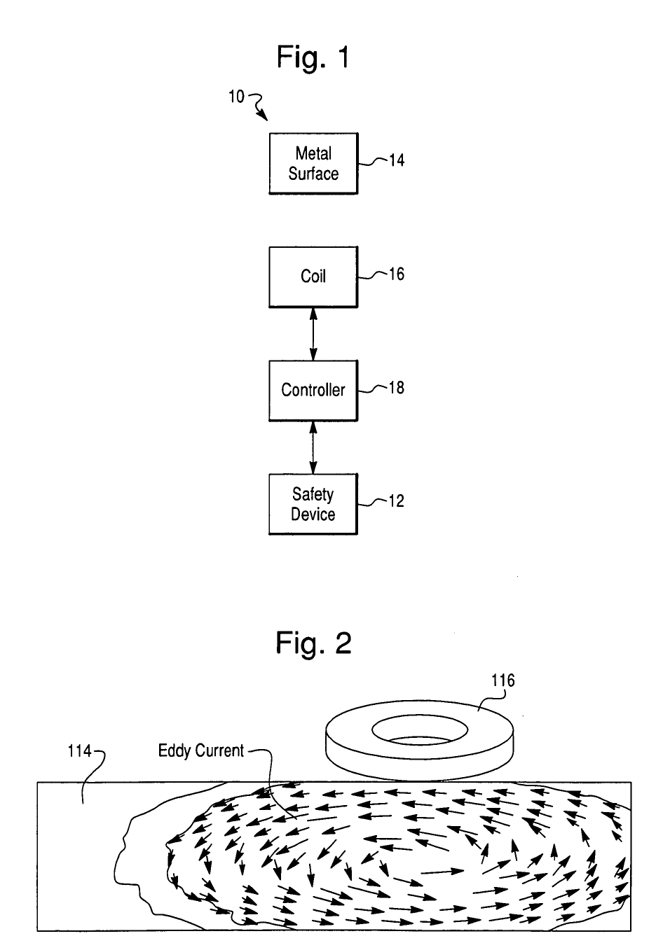

Referring to FIG. 1, a sensor system 10 is configured to actuate a safety device 12 based on a sensed impedance or inductance according to an exemplary embodiment. The sensor system 10 further includes an electrically conductive (e.g., metal) surface 14, a coil 16, and a controller 18. The safety device 12 is configured to provide a safety feature, for example to a vehicle occupant. According to one exemplary embodiment, the safety device 12 may be a side-impact airbag. According to another exemplary embodiment, the safety device 12 may be a front or rear-impact airbag. According to still another exemplary embodiment, the safety device 12 may be a seatbelt. According to other exemplary embodiments, the safety device 12 may be any safety device capable of being implemented in a vehicle.

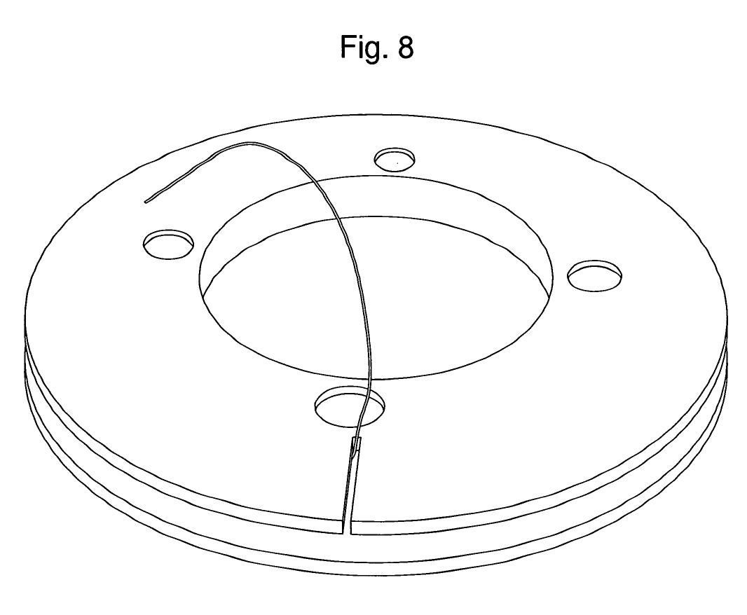

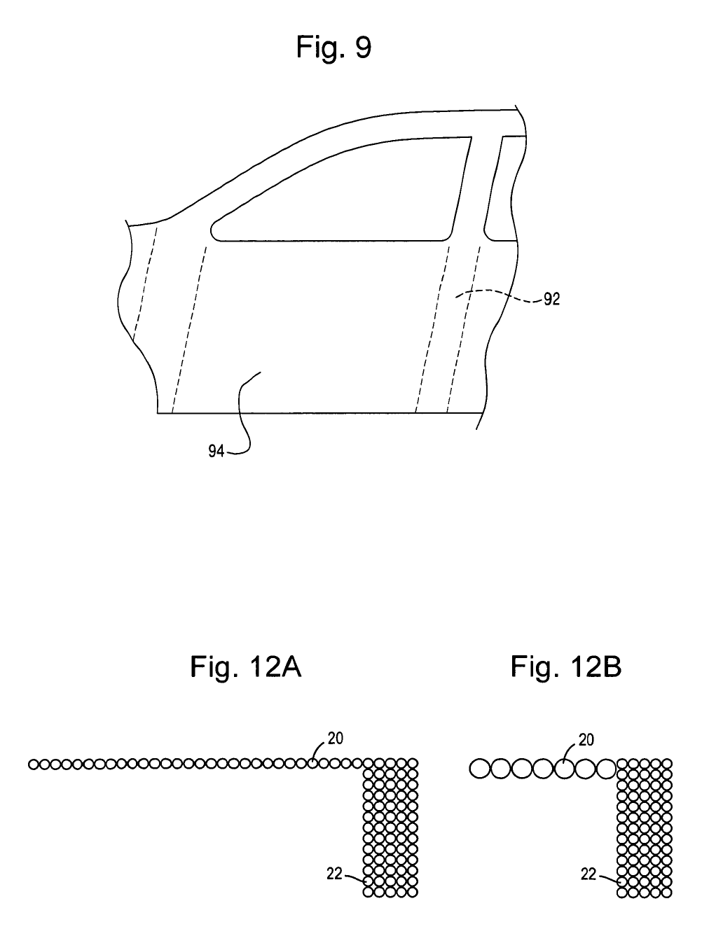

The electrically conductive surface 14 is typically composed of electrically conductive material such as aluminum, or a ferrous metal. According to other exemplary embodiments, the electrically conductive surface 14 may comprise any magnetically permeable material. As shown in FIG. 9, according to one exemplary embodiment, the electrically conductive surface 14 may be a vehicle door panel 94. According to another exemplary embodiment, the electrically conductive surface 14 may be a metal plate attached to a vehicle door panel. As shown in FIG. 9, according to yet another exemplary embodiment, the electrically conductive surface 14 may be a beam 92 or a target metal plate attached to the beam 92. According to other exemplary embodiments, the electrically conductive surface 14 may be any conductive material, metal plate or magnetically permeable material.

The coil 16, for example an air coil, is generally a coil capable of sensing movement of the electrically conductive surface 14. Typically, the winding pattern of the coil 16 allows increased sensitivity without a corresponding increase in impedance. The winding geometry of the coil 16 may provide a solution that meets vehicle packaging constraints while maintaining electrical characteristics used for impact sensing. The coil 16 is intended to have a reduced self inductance (the coil 16 in the air, or the coil 16 without the electrically conductive surface 14), maintain or increase the mutual-inductance to the electrically conductive surface 14, and maintain or reduce the impedance of the coil 16. The coil 16 with a smaller self-inductance and larger mutual-inductance to the surface plate 14 may yield a higher sensitivity to movement by the electrically conductive surface 14 (intrusion measurement), while the total impedance level of the sensor system 10 may be maintained or reduced. The winding pattern of the coil 16 may achieve lower self-inductance (without the electrically conductive surface 14 involved), while keeping the mutual-inductance of the sensor system 10 with the electrically conductive surface 14 as large as possible to create a high-sensitivity coil. In an exemplary embodiment where the coil 16 is used in a vehicle door, the coil 16 may be attached to an inner wall of the vehicle door. Alternatively, the coil 16 may attached to a beam within the vehicle door. The coil 16 may also be attached to or integrated with the controller 18.

The controller 18 is configured to provide electrical current to the coil 16, monitor changes in impedance or inductance due to the coil 16 interacting with the electrically conductive surface 14, and actuate the safety device 12 based on the changes with respect to a predefined threshold. According to various exemplary embodiments the controller 18 may be any hardware or software controller capable of managing current to the coil 16, monitoring changes in the coil 16 impedance, and actuating the safety device 12 based on the changes.

Referring to FIG. 2, the electromagnetic effect of an exemplary coil 116 with an exemplary electrically conductive surface 114 is illustrated. The electromagnetic effect includes an eddy current flow of electrons on and within the electrically conductive surface 114. If the electrically conductive surface 114 is moved closer to the coil 116 (increasing the strength of the electromagnetic effect), the density of the electrons in the eddy current will typically increase thus increasing the current developed in the electrically conductive surface 114 and the coil 116.

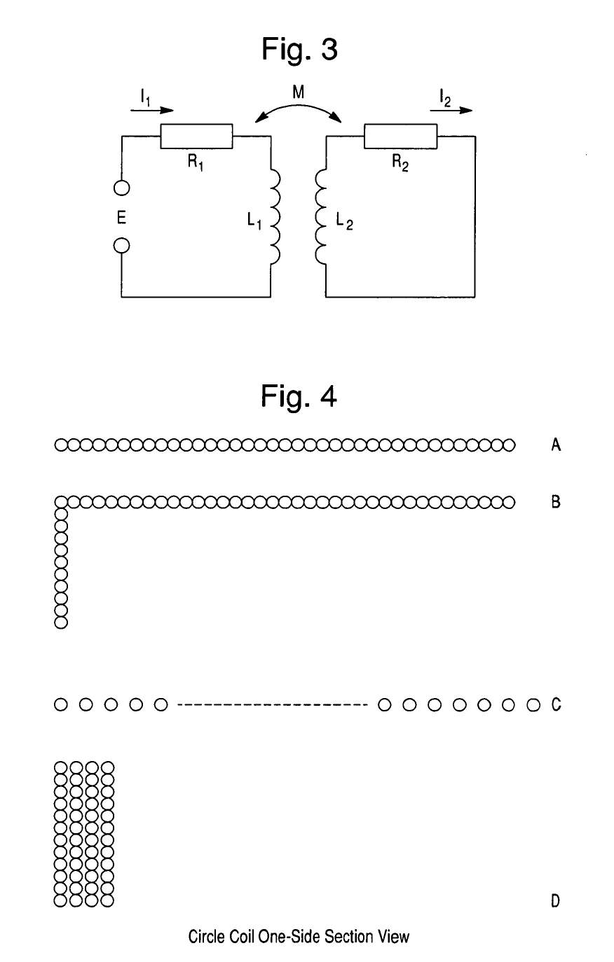

Referring to FIG. 3, an equivalent circuit of the electrically conductive surface 14 and interaction with the coil 16 is presented according to an exemplary embodiment. The coil 16 is represented by one inductor and resistor set (L1, R1) coupled to a power source E, while the electrically conductive surface 14 is represented by another inductor and resistor set (L2, R2). The system's impedance can be calculated by:

$$Z = \{ {R}_{1} + {R}_{2} \frac{{ω}^{2} {M}^{2}}{{R}_{2}^{2} + {( ω {L}_{2} )}^{2}} \} + j \{ ω {L}_{1} - ω {L}_{2} \frac{{ω}^{2} {M}^{2}}{{R}_{2}^{2} + {( ω {L}_{2} )}^{2}} \} \qquad ( 1 )$$

The real and imaginary parts of equation (1) are

Z=R+jωL or Z=R+jX (2)

The sensitivity of the measurement can be approximated by ΔZ/Z₌₀ in mathematical notation. Since the impedance and inductance of the coil 16 has a big influence in the sensor system 10, the main contribution of the ΔZ/Zₜ₌₀ may come from ΔX/Xₜ₌₀.

The ΔX/Xₜ₌₀ can be analyzed as follows, where:

$$X = ω \{ {L}_{1} - {L}_{2} \frac{{ω}^{2} {M}^{2}}{{R}_{2}^{2} + {( ω {L}_{2} )}^{2}} \} \qquad ( 3 )$$

In equation (3), L₁, the inductance of the coil 16 in the air, has a constant value. L₂, the inductance of the door in air related to the eddy current pattern, can be considered as constant if the permeability has only a minimum change under the sensor system (MSI) weak field. The same is true for R₂ and ω, which also have constant values, so the equation (3) can be re-written as:

L=L₁−KM² (4)

K has a constant value in the equation and thus the sensitivity is:

$$Δ X / {X}_{t = 0} = Δ L / {L}_{t = 0} = \frac{- 2 KM \cdot Δ M}{{L}_{1} - {KM}^{2}} {}_{t = 0} \qquad ( 5 )$$

In equation (5), only M is a function of intrusion; all other values are constants. To achieve a higher ΔX/Xₜ₌₀ value, M must be increased and L₁ decreased; or, the M level should be substantially maintained while allowing a significant drop in the L₁ value.

Similar conclusions can also be obtained from analysis of the real part of equation (1): ΔR/Rₜ₌₀.

Therefore, any coil section pattern or any coil shape design that yields a smaller L₁, and a larger M addressed by equation (5), may provide a relatively higher sensitivity of the intrusion measurement. Further, the number of winding turns of the coil 16 may control the total initial impedance level in the application.

Referring to FIG. 4, various coil 16 patterns (patterns A, B and C) may allow for higher sensitivity than that of the traditional winding of pattern D under similar conditions of coil size and winding number according to various exemplary embodiments. According to one exemplary embodiment, the coil 16 may include coil pattern A, a flat coil pattern. According to another exemplary embodiment, the coil 16 may include coil pattern B, an “L” shaped coil pattern. According to still another exemplary embodiment, the coil 16 may include coil pattern C. According to yet another exemplary embodiment, the coil 16 may include a coil pattern of a “U” shape. According to another exemplary embodiment, the coil 16 may include a coil pattern of an arch shape. According to other exemplary embodiments, the coil 16 may include any coil pattern that produces less impedance or less voltage to drive than the conventional coil pattern D under similar conditions of coil size and winding number.

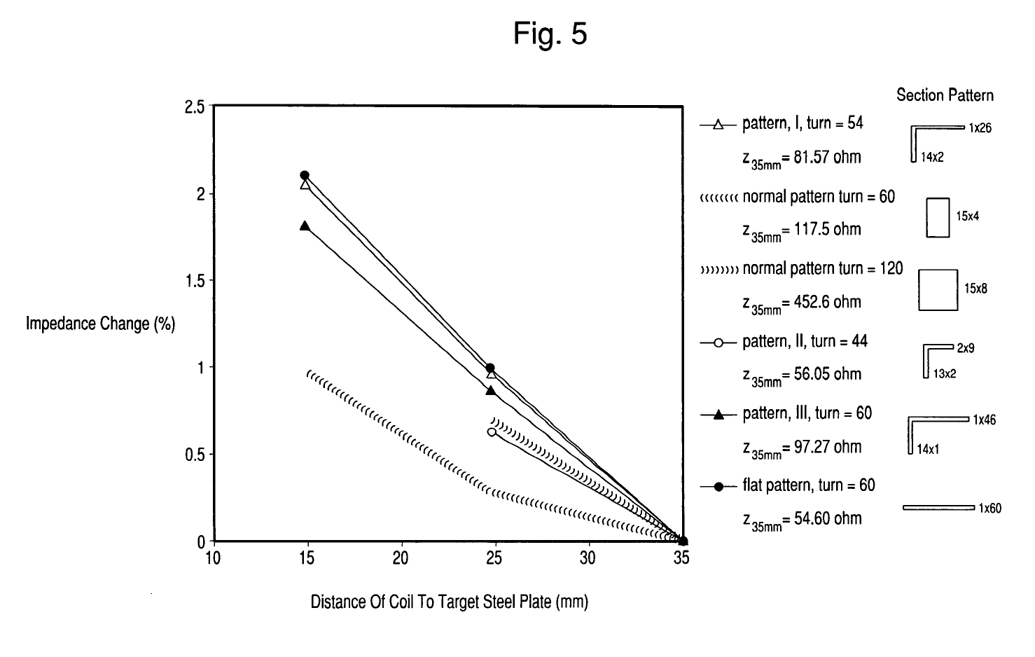

Referring to FIG. 5, a graph illustrates the impedance change between the coil 16 and the electrically conductive surface 14 when the coil 16 has various exemplary coil winding patterns according to an exemplary embodiment. As shown in FIG. 5, the initial distance between the electrically conductive surface 14 and the coil 16 is about 35 mm. The conventional square and rectangular shaped windings produce a small impedance change when the electrically conductive surface 14 approaches the coil 16. The “L” shaped and straight coil 16 winding patterns, as well as any winding pattern with a reduced number of adjacent windings produce a larger impedance change and thus a greater signal when the electrically conductive surface 14 approaches the coil 16. This larger impedance change produces a more rapidly changing signal during an intrusion event upon the door and allows the controller 18 to generate fewer false signals to the safety device 12. Further, due to the magnitude of the signal generated by the coil 16 having the non-square shaped patterns, the controller 18 can actuate a safety device 12 in less time than with the square-shaped coils.

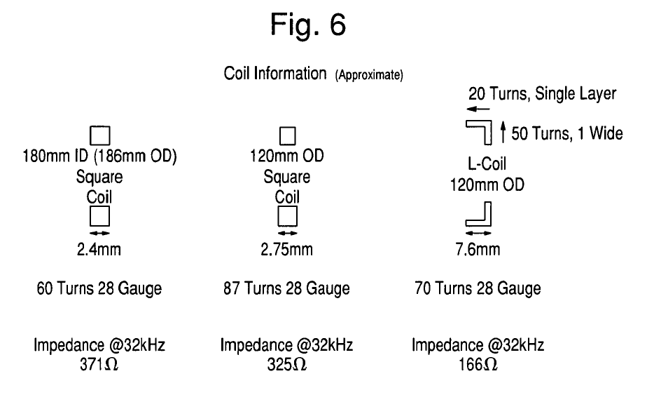

Referring to FIG. 6, cross-sections of two conventional square coil configurations of different sizes and an “L” shaped coil configuration are shown according to an exemplary embodiment. The single layer “L” shaped coil has a similar diameter (i.e., 120 mm) to the smaller of the two square configurations and thus uses less wire. This causes the “L” shaped coil to have a lower impedance than the conventional square configuration. Further the impedance of the “L” shaped coil at 32 KHz is significantly lower than that of than that of the square-shaped coils shown in FIG. 6.

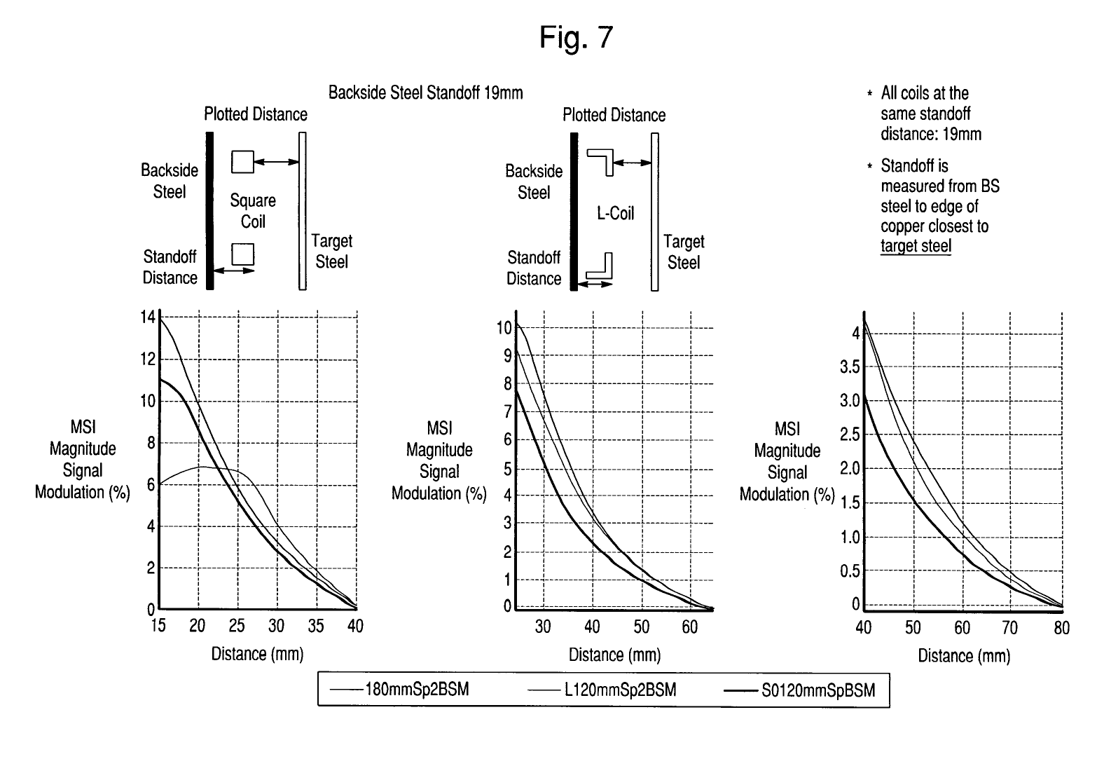

Referring to FIG. 7, a magnitude signal modulation (i.e., change in current through the coil 16) is illustrated for the coil 16 winding patterns of FIG. 6 in three graphs (A, B, and C) according to various exemplary embodiments. The coils 16 are attached to an exemplary steel backside (e.g., mounted 19 mm off) and configured to sense impedance or inductance of a target steel (electrically conductive) surface 14. As the plotted starting distance of the coil 16 from the electrically conductive surface 14 increases (e.g., about 40 mm in graph A, about 65 mm in graph B, and about 80 mm in graph C) the smaller “L” shaped coil results in signal performance (i.e., signal strength) similar to or better than that of a larger conventionally shaped coil when the distance between the coil 16 and the electrically conductive 14 is decreased.

Referring to FIG. 8, an exemplary coil 16 with an “L” shaped winding is illustrated. While an L-shape coil can gain the sensitivity and balance the impedance, it may be more difficult to control the winding to produce an L-shape coil than it is to produce a traditional flat, square or rectangular shaped winding. This difficulty may lead to the production of a coil with reduced quality.

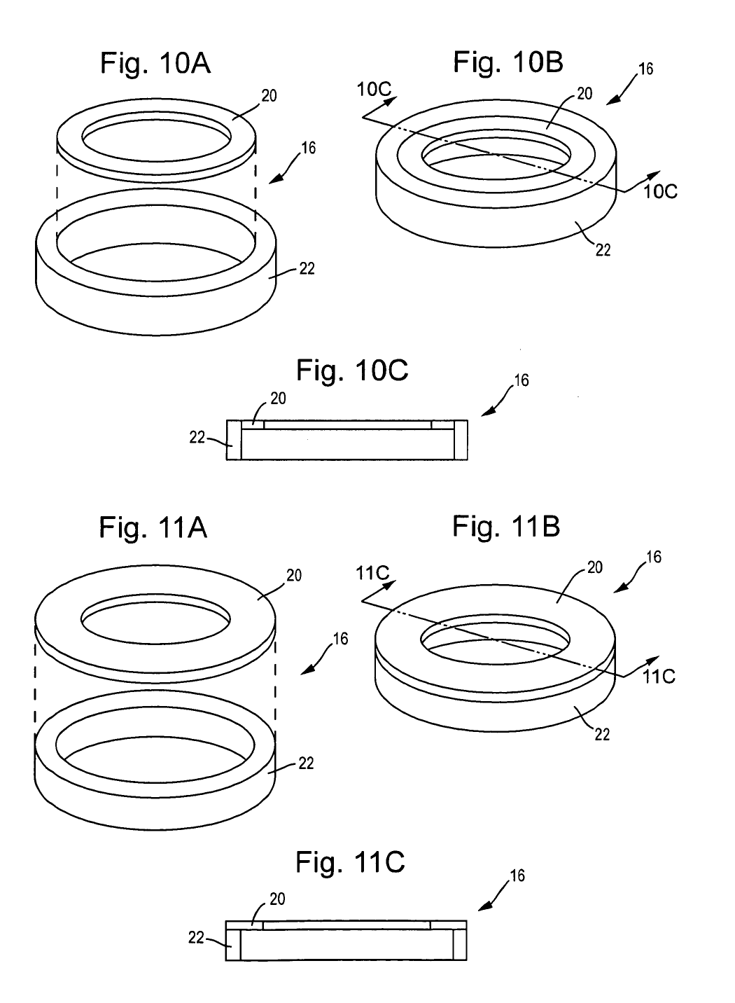

Referring to FIGS. 10A-11C, to avoid the difficulty of winding an unconventional “L” shaped coil, the “L” shaped coil may instead be formed from multiple conventional coils according to various exemplary embodiments. For example, the L coil can be assembled with a first or base coil 22 and a second or supplemental coil 20 in series. According to one exemplary embodiment, shown in FIGS. 10A-10C, supplemental coil 20 may be provided at least partially inside the base coil 22 (e.g., inside the top of the base coil 22). According to another exemplary embodiment, shown in FIGS. 11A-11C, supplemental coil 22 may be provided on the top of the base coil 22.

Each of the supplemental coil 20 and the base coil 22 may be configured for a different role. For example, the supplemental coil 20 may provide additional sensitivity and adjust the impedance of the system and the base coil 22 may dominate the major parts of design of the “L” shaped coil. The supplemental coil 20 and the base coil 22 may form a standardized, modular-type system. By regulating or standardizing the supplemental coil 20 and the base coil 22, each can be configured separately to form an “L” shaped coil with the desired properties.

The base coil 22 and the supplemental coil 20 may be formed from the same wire or may be formed with wire having different properties, for example, different materials, different thicknesses, different numbers of windings, different numbers of layers, etc. According to one exemplary embodiment, shown in FIG. 12A, the supplemental coil 20 comprises a number of turns (e.g., 30 turns) of a wire with the same diameter (e.g., 0.373 mm) as the wire forming the base coil 22. According to another exemplary embodiment, as shown in FIG. 12B, the supplemental coil 20 comprises a different number of turns (e.g., 7 turns) of a wire with a different diameter (e.g., 0.75 mm) as the wire forming the base coil 22. While FIGS. 12A and 12B illustrate a supplemental coil 20 with a single layer of windings, according to other exemplary embodiments, the supplemental coil 20 may comprise more than one layer. The base coil 22, according to an exemplary embodiment illustrated in both FIGS. 12A and 12B, comprises a number of layers of a number of generally concentric turns (e.g., a 13×5 coil).

According to still other exemplary embodiments, the supplemental coil 20 may be formed by printing a conductive path on an insulating base plate (e.g., similar to a printed circuit board). The base plate may also be configured as a coil-bracket for a structure support.

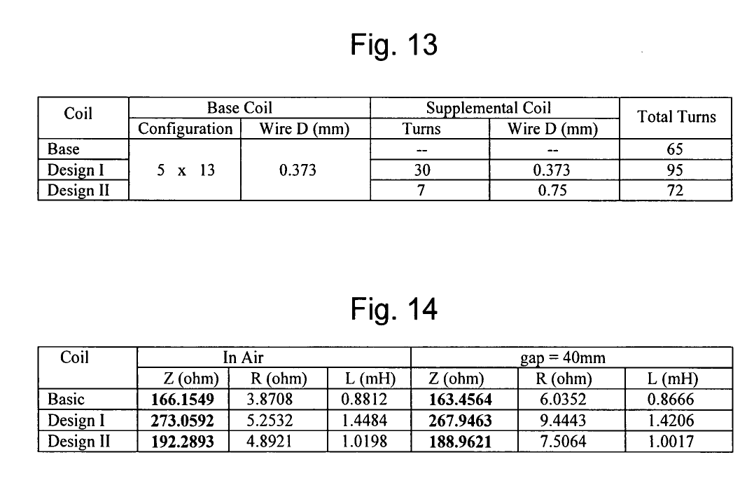

The properties of the “L” shaped coil changes depending on the presence of the supplemental coil 20 and the nature of the supplemental coil 20. FIG. 13 shows the layout parameters of the three coils, marked separately as “Base”, “Design I” (FIG. 12A) and “Design II” (FIG. 12B), according to an exemplary embodiment. The parameters for “Base” are for the base coil 22 as shown in FIGS. 12A and 12B with no supplemental coil 22. As observed, there is a sensitivity gain and impedance change in the “Design I” and “Design II”.

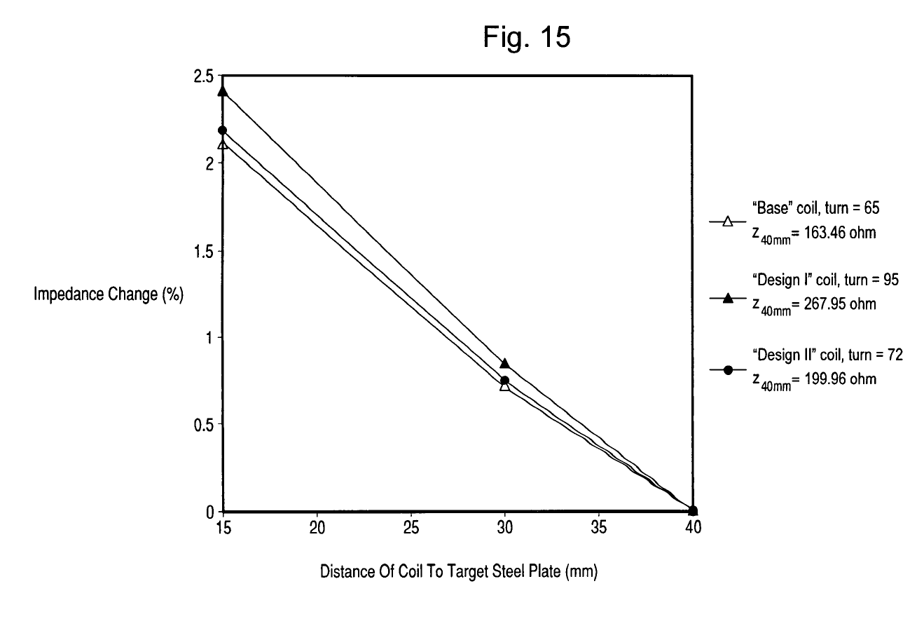

Referring to FIGS. 14 and 15, a table and a graph illustrate the impedance change between the coil 16 and the electrically conductive surface 14 when the coil 16 has various exemplary coil winding patterns described in FIG. 13. As shown in FIG. 15, the initial distance between the electrically conductive surface 14 and the coil 16 is 40 mm. The conventional rectangular shaped winding (“Base”) produce a small impedance change when the electrically conductive surface 14 approaches the coil 16. The “Design II” coil produces a larger impedance change and thus a greater signal when the electrically conductive surface 14 approaches the coil 16. The “Design I” coil produces an even larger impedance change and thus an even greater signal when the electrically conductive surface 14 approaches the coil 16. However, the “Design II” coil has an overall impedance between the “Base” coil and the “Design I” coil. By controlling both the size and type of wire as well as the number of turns used to form the supplementary coil 20, the sensitivity of the coil 16 can be increased without increasing the overall impedance of the coil 16.

The sensor systems described above may allow for a higher sensitivity measurement than conventional systems without increasing the total impedance level. The sensor systems may also be lower cost than conventional systems while being capable of generating a higher sensitivity measurement. The coils described above may be lower cost than conventional coils while allowing for a high sensitivity measurement without increasing the total impedance level.

Although the sensor system 10 is illustrated as including multiple features utilized in conjunction with one another, the sensor system 10 may alternatively utilize more or less than all of the noted mechanisms or features. For example, in other exemplary embodiments, the controller 18 may be a single unitary portion of the coil 16.

Although specific shapes of each element have been set forth in the drawings, each element may be of any other shape that facilitates the function to be performed by that element. For example, the coil windings have been shown to be of “L” shaped or flat patterns, however, in other embodiments the structure may define that of an arched, “U” shaped, or other form where the individual windings of the coil 16 are immediately next to fewer other windings than in the conventional square or rectangular design. While specific numbers of coil windings and winding layers have been shown, according to other exemplary embodiments, different numbers of windings and layers may be used.

For purposes of this disclosure, the term “coupled” means the joining of two components (electrical, mechanical, or magnetic) directly or indirectly to one another. Such joining may be stationary in nature or movable in nature. Such joining may be achieved with the two components (electrical or mechanical) and any additional intermediate members being integrally defined as a single unitary body with one another or with the two components or the two components and any additional member being attached to one another. Such joining may be permanent in nature or alternatively may be removable or releasable in nature

The present disclosure has been described with reference to example embodiments, however persons skilled in the art will recognize that changes may be made in form and detail without departing from the spirit and scope of the claimed subject matter. For example, although different example embodiments may have been described as including one or more features providing one or more benefits, it is contemplated that the described features may be interchanged with one another or alternatively be combined with one another in the described example embodiments or in other alternative embodiments. Because the technology of the present disclosure is relatively complex, not all changes in the technology are foreseeable. The present disclosure described with reference to the example embodiments and set forth in the following claims is manifestly intended to be as broad as possible. For example, unless specifically otherwise noted, the claims reciting a single particular element also encompass a plurality of such particular elements.

It is also important to note that the construction and arrangement of the elements of the system as shown in the preferred and other exemplary embodiments is illustrative only. Although only a certain number of embodiments have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter recited. For example, elements shown as integrally formed may be constructed of multiple parts or elements shown as multiple parts may be integrally formed, the operation of the assemblies may be reversed or otherwise varied, the length or width of the structures and/or members or connectors or other elements of the system may be varied, the nature or number of adjustment or attachment positions provided between the elements may be varied. It should be noted that the elements and/or assemblies of the system may be constructed from any of a wide variety of materials that provide sufficient strength or durability. Accordingly, all such modifications are intended to be included within the scope of the present disclosure. Other substitutions, modifications, changes and omissions may be made in the design, operating conditions and arrangement of the preferred and other exemplary embodiments without departing from the spirit of the present subject matter.

What is claimed is:

1. A sensor system, comprising:
an electrically conductive surface;
an air coil in proximity to the electrically conductive surface and comprising a first coil and a second coil, the first coil forming a wire winding pattern having a cross section perpendicular with the cross section of a wire winding pattern of the second coil;
a controller electrically coupled to the air coil and configured to sense a change in impedance of the air coil due to relative movement between the air coil and the electrically conductive surface; and
a safety device electrically coupled to the controller.

2. The sensor system of claim 1, wherein the air coil forms a wire winding pattern with an “L” shaped cross section;

3. The sensor system of claim 1, wherein the first coil comprises a greater number of winding layers than the second coil.

4. The sensor system of claim 1, wherein the first coil and the second coil are integrally formed from a single wire.

5. The sensor system of claim 1, wherein the first and second coils form rings, the second coil being positioned within an interior space of the first coil or the second coil being positioned on top of the first coil.

6. The sensor system of claim 1, wherein a wire of the first coil comprises a different material or thickness than a wire of the second coil.

7. The sensor system of claim 1, wherein the electrically conductive surface is a vehicle door panel comprised of metal, a metal plate attached to a vehicle door panel, a beam, or a target metal plate attached to a beam.

8. The sensor system of claim 1, wherein the safety device is a side-impact airbag, a front or rear-impact airbag, or a seatbelt.

9. The sensor system of claim 1, wherein the controller is configured to activate the safety device if the change in impedance of the air coil exceeds a predetermined threshold.

10. An air coil, comprising:
a first coil; and
a second coil, the first coil forming a wire winding pattern having a cross section perpendicular with the cross section of a wire winding pattern of the second coil;
wherein the air coil is in proximity to an electrically conductive surface and is electrically coupled to a controller configured to sense a change in impedance of the air coil due to relative movement between the coil and the electrically conductive surface, and wherein the controller is electrically coupled to a safety device.

11. The air coil of claim 10, wherein the air coil forms a wire winding pattern with an “L” shaped cross section;

12. The air coil of claim 10, wherein the first coil comprises a greater number of winding layers than the second coil.

13. The air coil of claim 10, wherein the first coil comprises a smaller number of winding turns than the second coil.

14. The air coil of claim 10, wherein the first and second coils form rings, the second coil being positioned within an interior space of the first coil or the second coil being positioned on top of the first coil.

15. The air coil of claim 10, wherein a wire of the first coil comprises a different material or thickness than a wire of the second coil.

16. The air coil of claim 10, wherein the electrically conductive surface is a vehicle door panel, a metal plate attached to a vehicle door panel, a beam, or a target metal plate attached to a beam.

17. The air coil of claim 10, wherein the safety device is a side-impact airbag, a front or rear-impact airbag, or a seatbelt.

18. The air coil of claim 10, wherein the controller is configured to activate the safety device if the change in impedance of the air coil exceeds a predetermined threshold.

19. A sensor system, comprising:
an electrically conductive surface;
an air coil in proximity to the electrically conductive surface and comprising a first coil and a second coil, the first coil forming a wire winding pattern having a cross section perpendicular with the cross section of a wire winding pattern of the second coil; and
a controller electrically coupled to the air coil and configured to sense a change in impedance of the air coil due to relative movement between the air coil and the electrically conductive surface.

20. The sensor system of claim 19, further comprising:
a safety device electrically coupled to the controller.
